(19) United States
(12) Patent Application Publication
(10) Pub. No.: US 2023/0255048 A1
(43) Pub. Date: Aug. 10, 2023

(54) DISPLAY DEVICE AND METHOD OF MANUFACTURING THE SAME

(71) Applicant: Samsung Display Co., LTD., Yongin-si (KR)

(72) Inventors: Seung Mook LEE, Yongin-si (KR); Chang Hee LEE, Yongin-si (KR); Yool Guk KIM, Yongin-si (KR); Young Mo KOO, Yongin-si (KR); Jae Kook HA, Yongin-si (KR)

(73) Assignee: Samsung Display Co., LTD., Yongin-si (KR)

(21) Appl. No.: 18/303,948

(22) Filed: Apr. 20, 2023

Related U.S. Application Data
(62) Division of application No. 17/034,820, filed on Sep. 28, 2020.

(30) Foreign Application Priority Data
Mar. 6, 2020 (KR) 10-2020-0028599

(51) Int. Cl. H10K 50/17; C09D 11/38; H10K 59/122; H10K 71/00; H10K 71/13

(52) U.S. Cl. CPC H10K 50/17; C09D 11/38; H10K 59/122; H10K 71/00; H10K 71/135; H10K 59/1201

(57) ABSTRACT

A display device includes a substrate on which pixels are defined, a pixel electrode disposed for each of the pixels on the substrate, a pixel defining layer disposed along a boundary of the pixels, the pixel defining layer including an opening exposing the pixel electrode, a light emitting layer disposed on the pixel electrode in the opening of the pixel defining layer, and a hole injection layer disposed between the pixel electrode and the light emitting layer. The hole injection layer includes an adhesion promoting layer disposed on the pixel electrode.

### CROSS-REFERENCE TO RELATED APPLICATION(S)

This is a divisional application of U.S. Pat. Application No. 17/034,820, filed Sep. 28, 2020 (now pending), the disclosure of which is incorporated herein by reference in its entirety. U.S. Pat. Application No. 17/034,820 claims priority to and benefit of Korean Patent Application No. 10-2020-0028599 under 35 U.S.C. §119, filed on Mar. 6, 2020 in the Korean Intellectual Property Office, the entire contents of which are incorporated herein by reference.

### BACKGROUND

### 1. Technical Field

The disclosure relates to a display device and a method of manufacturing the same.

### 2. Description of the Related Art

The importance of display devices has increased with the development of multimedia. Accordingly, various kinds of display devices such as Liquid Crystal Displays (LCDs) and Organic Light Emitting Display (OLEDs) have been used.

Among these display devices, an OLED displays an image by using an organic light emitting diode in which light is generated by a recombination of electrons and holes. The OLED has advantages such as high response speed, high luminance, a wide viewing angle, and is driven at low power consumption.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments may provide a display device capable of improving hole injectability of a light emitting device layer and light emitting efficiency according thereto while easily forming the light emitting device layer in an opening of a pixel defining layer, and a method of manufacturing the display device.

In accordance with an aspect of the disclosure, there may be provided a display device that may include a substrate on which pixels are disposed, a pixel electrode disposed for each of the pixels on the substrate, a pixel defining layer disposed along a boundary of the pixels, the pixel defining layer including an opening exposing the pixel electrode, a light emitting layer disposed on the pixel electrode in the opening of the pixel defining layer, and a hole injection layer disposed between the pixel electrode and the light emitting layer. The hole injection layer may include an adhesion promoting layer disposed on the pixel electrode.

A surface of the pixel defining layer may include repellant.

A surface of the pixel defining layer may include a fluoro group.

The adhesion promoting layer may include a self-assembled monolayer.

The adhesion promoting layer may be disposed in the opening of the pixel defining layer.

The adhesion promoting layer may include at least one of a siloxane compound and a phosphoric compound.

The adhesion promoting layer and a surface of the pixel electrode may form at least one of silicon-oxygen (Si-O) bonding and phosphorous-oxygen (P-O) bonding.

The adhesion promoting layer may be disposed on an entire surface of the pixel electrode.

The adhesion promoting layer may be partially disposed on the pixel electrode.

The display device may further include a self-assembled material dispersed in the hole injection layer.

The self-assembled material may include at least one of (3-aminopropyl)trimethoxysilane (APS), 11-mercaptoundecanoic acid (MUA), (3-trimethoxysilylpropyl)diethylenetriamine (DET), N-(2-aminoethyl)-3-aminopropyltrimethoxysilane (EDA), vinyltriethoxysilane (VTES), 3-glycidoxypropyltrimethoxysilane (GPTMS), 3-methacryloxypropyltrimethoxysilane (MPTMS), perfluorodecyltrichlorosilane (PFS), octadecyltrichlorosilane (OTS), octadecyltrimethoxysilane (OTMS), 1-hexadecanethiol (HDT), (heptadecafluoro-1,1,2,2,-tetrahydrodecyl)trichlorosilane (FDTS), 1H,1H,2H,2H-perfluorodecyltrichlorosilane-perfluorodecyltrichlorosilane (FOTS), pentafluorobenzenethiol (PFBT), and dichlorodimethylsilane (DDMS).

In accordance with another aspect of the disclosure, there may be provided a method of manufacturing a display device. The method may include disposing a pixel electrode on a substrate, disposing, on the substrate, a pixel defining layer including an opening exposing the pixel electrode; disposing an adhesion promoting layer and a hole injection layer in the opening of the pixel defining layer, and disposing a light emitting layer on the hole injection layer.

The disposing of the adhesion promoting layer and the hole injection layer may include disposing, in the opening, an ink which may include an adhesion promoting material and a hole injection material.

The adhesion promoting material may include a self-assembled material.

The adhesion promoting material may include a surfactant.

The disposing of the adhesion promoting layer and the hole injection layer may include disposing the adhesion promoting layer by disposing an adhesion promoting material in the opening, and disposing a hole injection material on the adhesion promoting layer.

The adhesion promoting material and the hole injection material may be disposed through inkjet printing.

The disposing of the pixel defining layer may include performing plasma treatment on a surface of the pixel defining layer.

The performing of the plasma treatment may include disposing repellant one the surface of the pixel defining layer by introducing a fluoro group onto the surface of the pixel defining layer.

The plasma treatment may use a reactive gas including at least one of SiF₄, CF₄, C₃F₈, C₂F₆, CHF₃, CClF₃, NF₃, and SF₆.

In accordance with the disclosure, the repellant or the surface of the pixel defining layer can be improved by the fluoro group of the surface of the pixel defining layer, so that the light emitting device layer can be easily formed in the opening of the pixel defining layer.

Further, the hole injection layer may include the adhesion promoting layer disposed on the pixel electrode, so that the wettability of the hole injection layer on the pixel electrode can be improved. Accordingly, the hole injection layer can be uniformly formed while being adhered closely onto one surface of the pixel electrode, and thus hole injectability and light emitting efficiency can be improved.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout.

FIG. 1 is a schematic plan view illustrating a display device in accordance with an embodiment of the disclosure.

FIG. 2 is a schematic circuit diagram illustrating a pixel of the display device shown in FIG. 1.

FIGS. 3 to 5 are schematic sectional views illustrating a pixel of the display device.

FIG. 6 is an enlarged schematic view of area A shown in FIG. 3.

FIGS. 7 to 11 are schematic sectional views illustrating process steps in a method of manufacturing a display device in accordance with an embodiment of the disclosure.

FIGS. 12 to 15 are schematic sectional views illustrating process steps in a method of manufacturing a display device in accordance with another embodiment of the disclosure.

### DETAILED DESCRIPTION OF THE EMBODIMENTS

The effects and characteristics of the disclosure and a method of achieving the effects and characteristics will be clear by referring to the embodiments described below in detail together with the accompanying drawings, where like elements are described with like reference characters. However, the disclosure is not limited to the embodiments disclosed herein but may be implemented in various forms. The embodiments are provided by way of example only so that a person of ordinary skilled in the art can fully understand the features in the disclosure and the scope thereof. Therefore, the disclosure can be defined by the scope of the appended claims, including any equivalents.

The term “on” that may be used to designate that an element or layer is on another element or layer includes both a case where an element or layer may be located directly on another element or layer, and a case where an element or layer may be located on another element or layer via still another element layer.

Although the terms “first,” “second,” and the like may be used for describing various components, these components are not confined by these terms. These terms are merely used for distinguishing one component from the other components. Therefore, a first component may be a second component or vice versa according to the technical concepts of the disclosure.

The term overlap may include layer, stack, face or facing, extending over, extending under, covering or partly covering or any other suitable term as would be appreciated and understood by those of ordinary skill in the art.

The phrase “at least one of” is intended to include the meaning of “at least one selected from the group of” for the purpose of its meaning and interpretation. For example, “at least one of A and B” may be understood to mean “A, B, or A and B.”

The term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

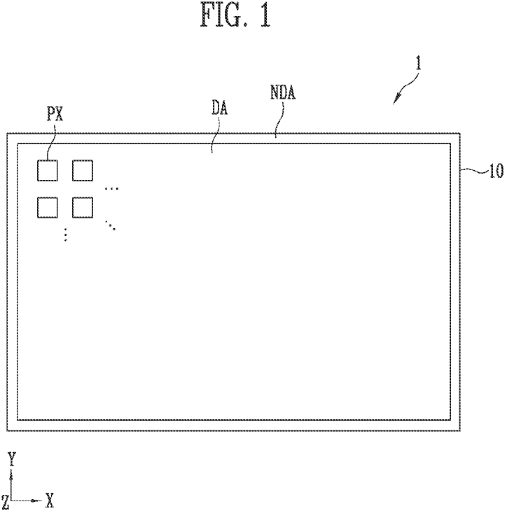

FIG. 1 is a schematic plan view illustrating a display device in accordance with an embodiment of the disclosure.

Referring to FIG. 1, the display device 1 may be a device for displaying a moving image or still image. The display device 1 may be used as a display screen for not only portable electronic devices such as a mobile phone, a smart phone, a tablet personal computer (PC), a smart watch, a watch phone, a mobile communication terminal, an electronic notebook, an electronic book, a portable multimedia player (PMP), a navigation system, and an ultra-mobile PC but also various products such as a television, a notebook computer, a monitor, an advertising board, and Internet of things.

The display device 1 may include a display panel 10. The display panel 10 may be a flexible substrate including a flexible polymer material such as polyimide. Accordingly, the display panel 10 may be curvable, bendable, foldable or rollable.

The display panel 10 may include a display area DA in which a screen may be displayed and a non-display area NDA in which the screen may not be displayed. The display panel 10 may be divided into the display area DA and the non-display area NDA on a plane. The non-display area NDA may be disposed to surround the display area DA.

The display area DA may include pixels PX. Each pixel PX may include a light emitting layer and a circuit layer for controlling a light emission amount of the light emitting layer. The circuit layer may include a line, an electrode, and at least one transistor. The light emitting layer may include an organic light emitting material. The light emitting layer may be encapsulated by the encapsulation layer.

The pixels PX may include a first color pixel, a second color pixel, and a third color pixel. In an embodiment, the first color pixel may be a red pixel, the second color pixel may be a blue pixel, and the third pixel may be a green pixel. However, the disclosure is not necessarily limited thereto.

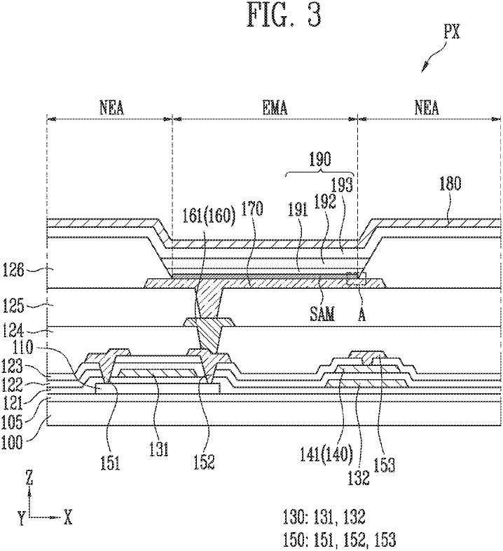

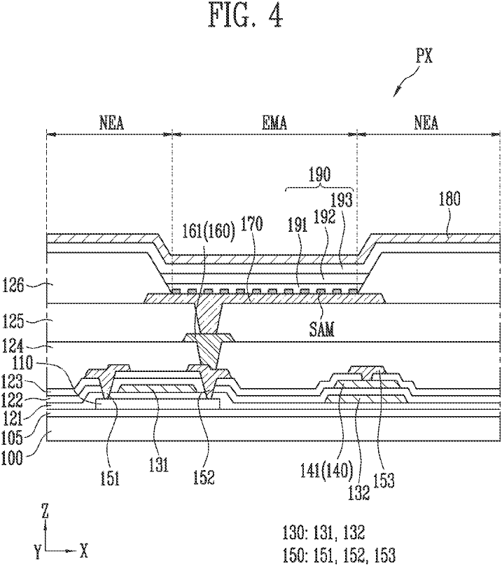

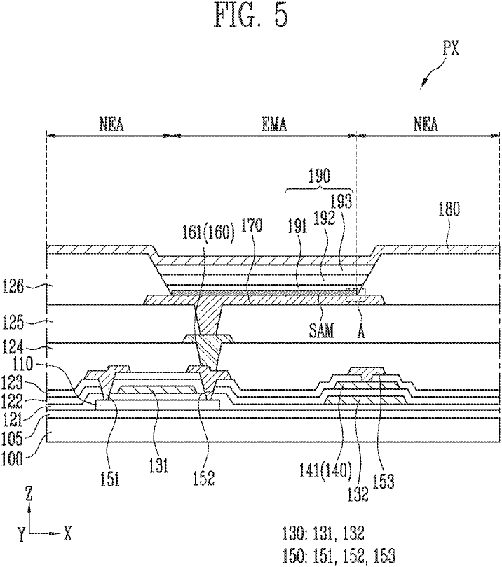

Each pixel PX may include a light emitting area (EMA shown in FIG. 3) and a non-light emitting area (NEA shown in FIG. 3) surrounding the light emitting area EMA. The light emitting areas EMA of the pixels PX may have different sizes, but the disclosure is not necessarily limited thereto. The light emitting area EMA of each pixel PX may have an approximately octagonal shape. However, the disclosure is not limited thereto, and the light emitting area EMA of each pixel PX may have a shape such as a hexagonal shape, a circular shape, a rhombic shape or another polygonal shape, or a polygonal shape having rounded corners.

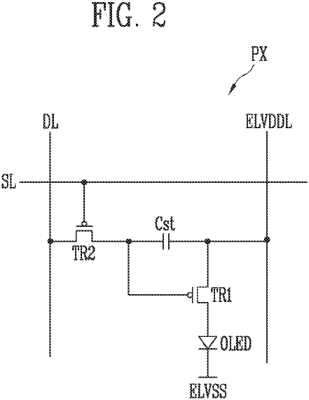

The pixels PX may be arranged in a matrix form. Pixels PX belonging to the same column may receive a data signal provided from the same data line, and pixels PX belonging to the same row may receive a scan signal provided from the same scan line. Each pixel PX may be driven by a pixel circuit. The pixel circuit may include transistors and at least one capacitor. A pixel circuit is illustrated in FIG. 2.

FIG. 2 is a schematic circuit diagram illustrating a pixel of the display device shown in FIG. 1.

Referring to FIG. 2, a pixel circuit may include a first transistor TR1, a second transistor TR2, a capacitor Cst, and an organic light emitting diode OLED. A scan line SL, a data line DL, and a first power voltage line ELVDDL may be electrically connected to the pixel circuit of the pixel PX.

The first transistor TR1 may be a driving transistor, and the second transistor TR2 may be a switching transistor. Although a case where both the first transistor TR1 and the second transistor TR2 may be implemented with a PMOS transistor is shown in the drawing, any one or both of the first transistor TR1 and the second transistor TR2 may be implemented with an NMOS transistor.

A first electrode (or source electrode) of the first transistor TR1 may be electrically connected to the first power voltage line ELVDDL, and a second electrode (or drain electrode) of the first transistor TR1 may be electrically connected to a pixel electrode (or anode electrode) of the organic light emitting diode OLED. A first electrode (or source electrode) of the second transistor TR2 may be electrically connected to the data line DL, and a second electrode (or drain electrode) of the second transistor TR2 may be electrically connected to a gate electrode of the first transistor TR1. A common electrode (or cathode electrode) of the organic light emitting diode OLED may receive a second power voltage ELVSS. The second power voltage ELVSS may be a voltage lower than a first power voltage provided from the first power voltage line ELVDDL.

The second transistor TR2 may output a data signal applied to the data line in response to a scan signal applied to the scan line SL. The capacitor Cst may charge a voltage corresponding to the data signal received from the second transistor TR2. The first transistor TR1 may control a driving control flowing through the organic light emitting diode OLED, corresponding to the quantity of charges stored in the capacitor Cst.

The equivalent circuit shown in FIG. 2 is merely one embodiment, and the pixel circuit may include a larger number of transistors (e.g., seven transistors) and a capacitor.

FIGS. 3 to 5 are schematic sectional views illustrating a pixel of the display device.

In FIGS. 3 to 5, the first transistor TR1 of the two transistors shown in FIG. 2 is exemplified in the form of a thin film transistor, and illustration of the second transistor TR2 is omitted.

A sectional structure of the pixel PX will be described in detail with reference to FIG. 3. The display panel may include a substrate 100, a buffer layer 105, a semiconductor layer 110, a first insulating layer 121, a gate conductive layer 130, a second insulating layer 122, a second gate conductive layer 140, a third insulating layer 123, a first data conductive layer 150, a fourth insulating layer 124, a second data conductive layer 160, a fifth insulating layer 125, a pixel electrode 170, a pixel defining layer 126 including an opening exposing the pixel electrode 170, a light emitting device layer 190 disposed in the opening of the pixel defining layer 126, and a common electrode 180 disposed on the light emitting device layer 190 and the pixel defining layer 126. Each of the above-described layers may be formed in a single layer, but be formed in a stacked layer including multiple layers. Another layer may be further disposed between the above-described layers.

The substrate 100 may support the layers disposed thereon. The substrate 100 may be made of an insulating material such as polymer resin. Examples of the polymer material may include polyethersulphone (PES), polyacrylate (PA), polyarylate (PAR), polyetherimide (PEI), polyethylene naphthalate (PEN), polyethylene terepthalate (PET), polyphenylene sulfide (PPS), polyallylate, polyimide (PI), polycarbonate (PC), cellulose triacetate (CAT), cellulose acetate propionate (CAP), and combinations thereof. The substrate 100 may be a flexible substrate which may be bendable, foldable, rollable, etc.

The buffer layer 105 may be disposed on the substrate 100. The buffer layer 105 may prevent diffusion of an impurity ion, prevent penetration of moisture or external air, and perform a surface planarization function. The buffer layer 105 may include silicon nitride, silicon oxide, silicon oxynitride, or the like. The buffer layer 105 may be omitted according to a kind of the substrate 100, a process condition, or the like.

The semiconductor layer 110 may be disposed on the buffer layer 105. The semiconductor layer 110 may form a channel of a thin film transistor of the pixel PX. The semiconductor layer 110 may include polycrystalline silicon. However, the disclosure is not limited thereto, and the semiconductor layer 110 may include single crystalline silicon, low temperature crystalline silicon, amorphous silicon, an oxide semiconductor, or a combination thereof. The oxide semiconductor may include, for example, a two component-based compound (Abx), a three component-based compound (AbxCy), or a four component-based compound (AbxCyDz), which may include indium (In), zinc (Zn), gallium (Ga), tin (Sn), titanium (Ti), aluminum (Al), hafnium (Hf), zirconium (Zr), magnesium (Mg), etc., or a combination thereof

The first insulating layer 121 may be disposed over the semiconductor layer 110. The first insulating layer 121 may be roughly disposed throughout the entire surface of the substrate 100. The first insulating layer 121 may be a gate insulating layer having a gate insulating function. The first insulating layer 121 may include a silicon compound, a metal oxide, etc., or a combination thereof. For example, the first insulating layer 121 may include silicon oxide, silicon nitride, silicon oxynitride, aluminum oxide, tantalum oxide, hafnium oxide, zirconium oxide, titanium oxide, etc., which may be used solely or as a combination thereof. The first insulating layer 121 may be a multi-layer formed in a single layer or a stacked layer of different materials.

The first gate conductive layer 130 may be disposed on the first insulating layer 121. The first gate conductive layer 130 may include a gate electrode 131 of the thin film transistor of the pixel PX, a scan line electrically connected to the gate electrode 131, and a sustain capacitor first electrode 132.

The first gate conductive layer 130 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chrome (Cr), calcium (Ca), titanium (Ti), tungsten (W), and copper (Cu). The first gate conductive layer 130 may be a single layer or a multi-layer.

The second insulating layer 122 may be disposed over the first gate conductive layer 130. The second insulating layer 122 may be an interlayer insulating layer or a gate insulating layer. The second insulating layer 122 may include an inorganic insulating material such as silicon oxide, silicon nitride, silicon oxynitride, hafnium oxide, aluminum oxide, titanium oxide, tantalum oxide, zinc oxide, or a combination thereof.

The second gate conductive layer 140 may be disposed on the second insulating layer 122. The second gate conductive layer 140 may include a sustain capacitor second electrode 141. The second gate conductive layer 140 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chrome (Cr), calcium (Ca), titanium (Ti), tungsten (W), and copper (Cu). The second gate conductive layer 140 may be made of the same material as the first gate conductive layer 130, but the disclosure is not limited thereto. The second gate conductive layer 140 may be a single layer or a multi-layer.

The third insulating layer 123 may be disposed over the second gate conductive layer 140. The third insulating layer 123 may include an inorganic insulating material such as silicon oxide, silicon nitride, silicon oxynitride, hafnium oxide, aluminum oxide, titanium oxide, tantalum oxide, zinc oxide, or a combination thereof, or an organic insulating material such as polyacrylates resin, epoxy resin, phenolic resin, polyamides resin, polyimides resin, unsaturated polyesters resin, polyphenylenethers resin, polyphenylenesulfides resin, benzocyclobutene (BCB), or a combination thereof. The third insulating layer 123 may be a single layer or a multi-layer formed in a stacked layer of different materials.

The first data conductive layer 150 may be disposed on the third insulating layer 123. The first data conductive layer 150 may be a first source/drain conductive layer. The first data conductive layer 150 may include a first electrode 151 and a second electrode 152 of the thin film transistor of the pixel PX. The first electrode 151 and the second electrode 152 of the thin film transistor may be electrically connected to a source region and a drain region of the semiconductor layer 110 through contact holes penetrating the third insulating layer 123, the second insulating layer 122, and the first insulating layer 121. A first power voltage electrode 153 of the pixel PX may constitute the first data conductive layer 150.

The first data conductive layer 150 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chrome (Cr), calcium (Ca), titanium (Ti), tungsten (W), and copper (Cu). The first data conductive layer 150 may be a single layer or a multi-layer. For example, the first data conductive layer 150 may be formed in a stacked structure of Ti/Al/Ti, Mo/Al/Mo, Mo/AlGe/Mo, Ti/Cu, or the like.

The fourth insulating layer 124 may be disposed over the first data conductive layer 150. The fourth insulating layer 124 may cover the first data conductive layer 150. The fourth insulating layer 124 may be an interlayer insulating layer or a via layer. The fourth insulating layer 124 may include an organic insulating material such as polyacrylates resin, epoxy resin, phenolic resin, polyamides resin, polyimides resin, unsaturated polyesters resin, polyphenylenethers resin, polyphenylenesulfides resin, benzocyclobutene (BCB), or a combination thereof.

The second data conductive layer 160 may be disposed on the fourth insulating layer 124. The second data conductive layer 160 may be a second source/drain conductive layer. The second data conductive layer 160 may include a connection electrode 161 of the pixel PX. The connection electrode 161 may be electrically connected to the second electrode 152 of the thin film transistor of the pixel PX through a contact hole penetrating the fourth insulating layer 124.

The second data conductive layer 160 may include at least one metal selected from molybdenum (Mo), aluminum (Al), platinum (Pt), palladium (Pd), silver (Ag), magnesium (Mg), gold (Au), nickel (Ni), neodymium (Nd), iridium (Ir), chrome (Cr), calcium (Ca), titanium (Ti), tungsten (W), and copper (Cu). The second data conductive layer 160 may be a single layer or a multi-layer. The second data conductive layer 160 may be made of the same material as the first data conductive layer 150, but the disclosure is not limited thereto.

The fifth insulating layer 125 may be disposed over the second data conductive layer 160. The fifth insulating layer 125 may cover the second data conductive layer 160. The fifth insulating layer 125 may be a via layer. The fifth insulating layer 125 may include the same material as the fourth insulating layer 124, or include at least one material selected from the materials exemplified as the material constituting the fourth insulating layer 124.

The pixel electrode 170 may be disposed on the fifth insulating layer 125. The pixel electrode 170 may be an anode electrode of a light emitting device. The pixel electrode 170 may be electrically connected to the connection electrode 161 constituting the second conductive layer 160 through a contact hole penetrating the fifth insulating layer 125, and accordingly, be electrically connected to the second electrode 152 of the thin film transistor. The pixel electrode 170 may at least partially overlap the light emitting area EMA of the pixel PX.

The pixel electrode 170 may have a stacked layer structure in which a material layer having a high work function such as Indium Tin Oxide (ITO), Indium Zinc Oxide (IZO), Zinc Oxide (ZnO), Indium Oxide (In₂O₃), or a combination thereof, and a reflective material layer such as silver (Ag), magnesium (Mg), aluminum (Al), platinum (Pt), lead (Pd), gold (Au), nickel (Ni), neodymium (Nd), iridium (Ir), chromium (Cr), lithium (Li), calcium (Ca) or a mixture thereof are stacked, but the disclosure is not limited thereto. A layer having a high work function may be further disposed above the reflective material layer to be disposed close to the light emitting device layer 190. The pixel electrode 170 may have a multi-layered structure of ITO/Mg, ITO/MgF, ITO/Ag, or ITO/Ag/ITO, but the disclosure is not limited thereto.

The pixel defining layer 126 may be disposed over the pixel electrode 170. The pixel defining layer 126 may at least partially overlap the non-light emitting area NEA of the pixel PX. The pixel defining layer 126 may include an opening exposing the pixel electrode 170. The pixel defining layer 126 may include an inorganic insulating material such as silicon oxide, silicon nitride, silicon oxynitride, hafnium oxide, aluminum oxide, titanium oxide, tantalum oxide, zinc oxide, or a combination thereof, or an organic insulating material such as polyacrylates resin, epoxy resin, phenolic resin, polyamides resin, polyimides resin, unsaturated polyesters resin, polyphenylenethers resin, polyphenylenesulfides resin, benzocyclobutene (BCB), or a combination thereof.

A surface of the pixel defining layer 126 may include a fluoro group (F). The repellant of the surface of the pixel defining layer 126 can be improved by the fluoro group (F). Accordingly, the light emitting device layer 190 of a specific pixel PX can be prevented from invading the light emitting area EMA of an adjacent pixel PX beyond the pixel defining layer 126 in a process of forming the light emitting device layer 190. The fluoro group (F) of the surface of the pixel defining layer 126 may be formed through a fluorine plasma process. This will be described in detail later with reference to FIG. 8.

The light emitting device layer 190 may be disposed in the opening of the pixel defining layer 126. The light emitting device layer 190 may include a hole injection layer 191, a light emitting layer 192, and an electron injection layer 193.

The hole injection layer 191 may be disposed on the pixel electrode 170 in the opening of the pixel defining layer 126. The hole injection layer 191 may be disposed between the pixel electrode 170 and the light emitting layer 192. The hole injection layer 191 may function to improve hole injection efficiency from the pixel electrode 170 to the light emitting layer 192. For example, the hole injection layer 191 may include, as a hole injection material, at least one material among poly(3,4-ethylenedioxythiophene/styrenesulfonic acid (PEDOT/PSS), polythiophene and its derivatives, polyaniline and its derivatives, and polypyrrole and its derivatives, but the disclosure is not necessarily limited thereto. A hole transport layer may be further disposed between the hole injection layer 191 and the light emitting layer 192, or the hole injection layer 191 may further include a hole transport material in addition to the hole injection material. The hole transport layer and/or the hole transport material may function to improve the transportability (injectability) of holes with respect to the light emitting layer 192, and simultaneously, to suppress electrons from invading from the light emitting layer 192 to the hole injection layer 191.

The hole injection layer 191 may further include an adhesion promoting layer SAM in addition to the above-described hole injection material. The adhesion promoting layer SAM may be disposed in the opening of the pixel defining layer 126. The adhesion promoting layer SAM may be disposed throughout the entire surface of the pixel electrode 170, which may be exposed by the pixel defining layer 126. However, the disclosure is not necessarily limited thereto, and the adhesion promoting layer SAM may be partially disposed on one surface of the pixel electrode 170 as shown in FIG. 4. For example, the adhesive promoting layer SAM may exist in an island shape on the one surface of the pixel electrode 170. The adhesion promoting layer SAM will be described in detail with reference to FIG. 6. FIG. 6 is an enlarged schematic view of area A shown in FIG. 3.

Referring to FIG. 6, the adhesion promoting layer SAM may be a self-assembled monolayer (SAM). For example, the adhesion promoting layer SAM may be an organic monolayer spontaneously formed on the surface of the pixel electrode 170. The adhesion promoting layer SAM may be regularly aligned on the surface of the pixel electrode 170.

The adhesion promoting layer SAM may be chemically adsorbed on the surface of the pixel electrode 170. Specifically, the adhesion promoting layer SAM may be configured with a reactive group of a head part coupled to the pixel electrode 170, an alkyl chain of a body part which enables formation of a regular molecular layer, and a functional group of a tail part.

The reactive group of the adhesion promoting layer SAM may be chemically adsorbed on the surface of the pixel electrode 170. The reactive group of the adhesion promoting layer SAM may be chemically bonded to the surface (e.g., directly to the surface) of the pixel electrode 170.

For example, the adhesion promoting layer SAM may be an alkylsiloxane self-assembled monolayer, and include a siloxane-based compound. The reactive group of the adhesion promoting layer SAM may form silicon-oxygen (Si-O) bonding to the surface of the pixel electrode 170. However, the disclosure is not limited thereto. The adhesion promoting layer SAM may be an alkane phosphate self-assembled monolayer, and include a phosphonate compound. The reactive group of the adhesion promoting layer SAM may form phosphorous-oxygen (P-O) bonding to the surface of the pixel electrode 170.

The alkyl chain of the adhesion promoting layer SAM may be configured with a substituted or unsubstituted C1-C20 alkyl group. A monolayer aligned on the surface of the pixel electrode 170 may be formed due to Van der Waals interaction between alkyl chains of the adhesion promoting layer SAM.

The functional group of the adhesion promoting group may have a hydrophilic or hydrophobic functional group.

The adhesion promoting layer SAM having the hydrophilic functional group may include a material made of (3-aminopropyl)trimethoxysilane (APS), 11-mercaptoundecanoic acid (MUA), (3-trimethoxysilylpropyl)diethylenetriamine (DET), N-(2-aminoethyl)-3-aminopropyltrimethoxysilane (EDA), and any combination thereof, but the disclosure is not limited thereto.

The adhesion promoting layer SAM having the hydrophobic functional group may include a material made of vinyltriethoxysilane (VTES), 3-glycidoxypropyltrimethoxysilane (GPTMS), 3-methacryloxypropyltrimethoxysilane (MPTMS), perfluorodecyltrichlorosilane (PFS), octadecyltrichlorosilane (OTS), octadecyltrimethoxysilane (OTMS), 1-hexadecanethiol (HDT), (heptadecafluoro-1,1,2,2,-tetrahydrodecyl)trichlorosilane (FDTS), 1H,1H,2H,2H-perfluorodecyltrichlorosilane-perfluorodecyltrichlorosilane (FOTS), pentafluorobenzenethiol (PFBT), dichlorodimethylsilane (DDMS), and any combination thereof, but the disclosure is not limited thereto.

In some embodiments, in case that the adhesion promoting layer SAM and the hole injection layer 191 are formed through the same process, the hole injection layer 191 may contain a very small amount of material constituting the adhesion promoting layer SAM. The adhesion promoting layer SAM and/or the hole injection layer 191 may further include a surfactant. The surfactant is not particularly limited, and may include a nonionic surfactant, a cationic surfactant, and/or an anionic surfactant, which are used in the art.

The nonionic surfactant may include, for example, an amphoteric surfactant including polyoxyethyleneoleylether, polyoxyethylenelaurylether, polyoxyethylenenonylphenylether, polyoxyethylenealkyletherphosphateester, polyoxyethylenesorbitanmonostearate, polyethyleneglycolmonolaurate, alkylbetaine such as alkylmethylaminoacetatebetaine, or alkylimidazolin, a fluorine-based surfactant, and/or a silicon-based surfactant.

The cationic surfactant may include, for example, alkyl quaternary ammonium salts or ethylene oxide adducts thereof.

The anionic surfactant may include polyoxyethylenealkylethersulphate, dodecylbenzenesulphonate, alkali salt of a styrene-acrylate copolymer, alkylnaphthalenesulphonate, alkyldiphenyletherdisulphonate, laurylsurphatemonoethanolaime, sodium stearate, lauryl sodium sulfate, monoethanolamine of a styrene-acrylate copolymer, and/or polyoxyethylenealkyletherphosphateester.

As described above, in case that the hole injection layer 191 includes the adhesion promoting layer SAM on the pixel electrode 170, the wettability of the hole injection layer 191 with respect to the pixel electrode 170 can be improved. Accordingly, the hole injection layer 191 may be uniformly formed while being adhered closely onto the one surface of the pixel electrode 170, and thus hole injectability and light emitting efficiency can be improved.

Referring back to FIG. 3, the light emitting layer 192 may be disposed on the hole injection layer 191. The light emitting layer 192 may be made of an inorganic material or an organic material. The light emitting layer 192 may overlap the light emitting area EMA of the pixel PX.

The electron injection layer 193 may be disposed on the light emitting layer 192. The electron injection layer 193 may be disposed in not only the light emitting area EMA of the pixel PX but also the non-light emitting area NEA. For example, the electron injection layer 193 may be disposed on the entire surface of each pixel PX. However, the disclosure is not limited thereto, and the electron injection layer 193 may be partially disposed in the opening of the pixel defining layer 126 as shown in FIG. 5. For example, the electron injection layer 193 may overlap the light emitting area EMA of the pixel PX. The electron injection layer 193 may function to improve electron injection efficiency from the common electrode 180 which will be described later to the light emitting layer 192. The electron injection layer 193 may include, for example, an inorganic insulating material and/or an inorganic semiconductor material. Examples of the inorganic insulating layer may be alkali metal chalcogenide (oxide, sulfide, selenide, or telluride), alkali earth metal chalcogenide, halide of alkali metal, halide of alkali earth metal, and the like. These materials may be used alone or in combination of two or more.

An electron transport layer may be further disposed between the electron injection layer 193 and the light emitting layer 192, or the electron injection layer 193 may further include an electron transport material in addition to the electron injection material. The electron transport layer may function to transport electrons injected from the common electrode 180 and the electron injection layer 193 to the light emitting layer 192. The electron transport layer and/or the electron transport material may include, for example, at least one of quinoline derivatives such as an organic metal complex having 8-quinolinol such as tris(8-quinolinolato)aluminum (Alq3) or a derivative thereof as a ligand, oxadiazole derivatives, perylene derivatives, pyridine derivatives, pyrimidine derivatives, quinoxaline derivatives, diphenylquinone derivatives, and nitro-substituted fluorene derivatives.

The common electrode 180 may be disposed on the light emitting layer 190 and the pixel defining layer 126. The common electrode 180 may be a cathode electrode of the light emitting device. The common electrode 180 may be disposed in not only the light emitting area EMA of the pixel PX but also the non-light emitting area NEA. For example, the common electrode 180 may be disposed on the entire surface of each pixel PX. The common electrode 180 may include a material layer having a low work function, such as Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg). The common electrode 180 may further include a transparent metal oxide layer disposed on the material layer having the low work function.

Although not shown in the drawing, an encapsulation layer may be disposed on top of the common electrode 180. The encapsulation layer may include an inorganic layer. In an embodiment, the encapsulation layer may include a first inorganic layer, an organic layer on top of the first inorganic layer, and a second inorganic layer on top of the organic layer.

According to the display device in accordance with the above-described embodiment, the repellant of the surface of the pixel defining layer 126 can be improved by the fluoro group on the surface of the pixel defining layer 126. Accordingly, the light emitting device layer 190 can be easily formed in the opening of the pixel defining layer 126 of a specific pixel PX.

The hole injection layer 191 may include the adhesion promoting layer SAM disposed on the pixel electrode 170, so that the wettability of the hole injection layer 191 with respect to the pixel electrode 170 can be improved. Accordingly, the hole injection layer 191 may be uniformly formed while being adhered closely onto the one surface of the pixel electrode 170, and thus hole injectability and light emitting efficiency can be improved.

Methods of manufacturing the display device in accordance with embodiments of the disclosure will be described.

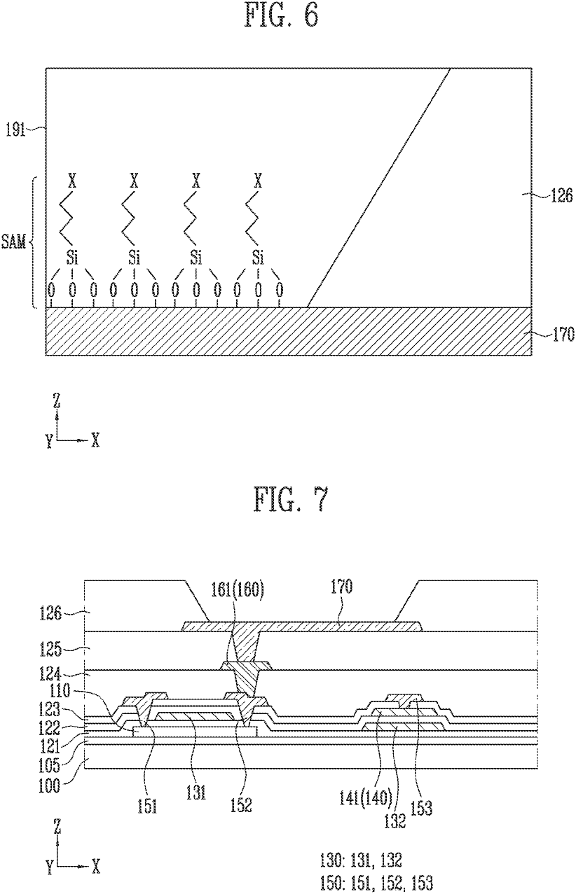

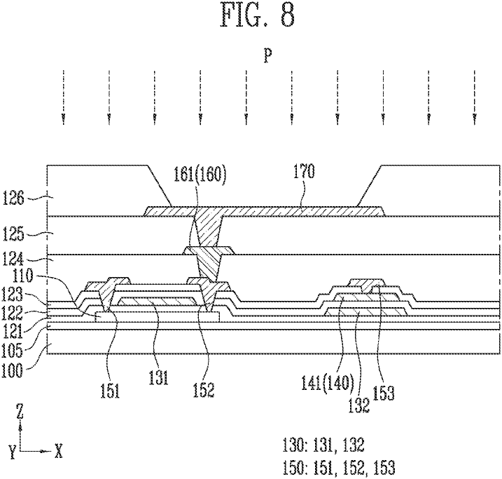

FIGS. 7 to 11 are schematic sectional views illustrating process steps in a method of manufacturing a display device in accordance with an embodiment of the disclosure. Hereinafter, components substantially identical to those shown in FIGS. 1 to 6 are designated by like reference numerals, and detailed descriptions of the same reference numerals will be omitted.

Referring to FIG. 7, first, a substrate 100 on which a pixel electrode 170 and the like may be formed may be prepared, and a pixel defining layer 126 including an opening exposing the pixel electrode 170 may be formed on the substrate 100. The substrate 100 including the pixel electrode 170 has been described with reference to FIGS. 1 to 6, and therefore, redundant descriptions will be omitted.

The pixel defining layer 126 may be formed by forming, on the substrate 100, an organic layer including at least one organic material among, for example, polyacrylates resin, epoxy resin, phenolic resin, polyamides resin, polyimides resin, unsaturated polyesters resin, polyphenylenethers resin, polyphenylenesulfides resin, and benzocyclobutene (BCB) and then patterning the organic layer through exposure and development processes.

Referring to FIG. 8, subsequently, plasma treatment P may be performed on one surface of the pixel defining layer 126. Repellant may be provided to a surface of the pixel defining layer 126 by introducing a fluoro group onto the surface of the pixel defining layer 126 through the plasma treatment P. A light emitting device layer 190 which will be described later can be easily formed in an opening of the pixel defining layer 126 due to the repellant of the surface of the pixel defining layer 126. In order to introduce the fluoro group, the plasma treatment P may use a reactive gas including at least one of SiF₄, CF₄, C₃F₈, C₂F₆, CHF₃, CClF₃, NF₃, and SF₆, but the disclosure is not necessarily limited thereto. A residual substance or residual layer, which may exist on the pixel electrode 170, may be removed through the plasma treatment P. A separate descum process for removing the residual substance or residual layer of the pixel electrode 170 may be omitted. For example, device characteristics can be improved, and simultaneously, economic feasibility can be ensured.

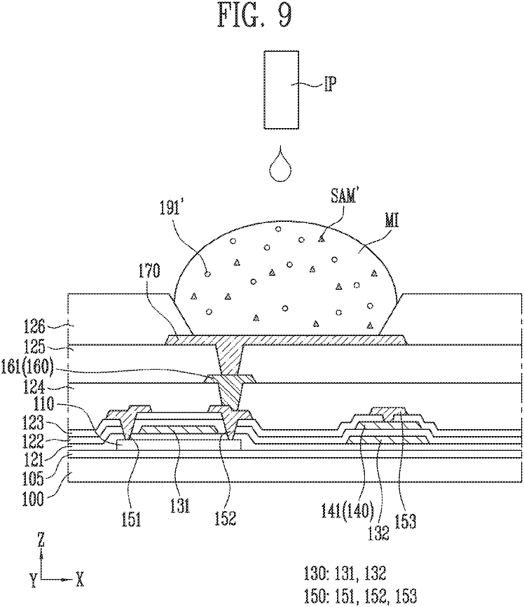

Referring to FIG. 9, subsequently, a mixed ink MI in which a hole injection material 191′ and an adhesion promoting material SAM′ are mixed together may be provided on the pixel electrode 170 exposed by the opening of the pixel defining layer 126. In case that a hole injection layer 191 may be formed by mixing the hole injection material 191′ and the adhesion promoting material SAM′ as described above, the wettability of the mixed ink MI with respect to the pixel electrode 170 can be improved. Thus, the mixed ink MI can be uniformly coated while being adhered closely to one surface of the pixel electrode 170.

The hole injection material 191′ may include at least one material among, for example, poly(3,4-ethylenedioxythiophene/styrenesulfonic acid (PEDOT/PSS), polythiophene and its derivatives, polyaniline and its derivatives, and polypyrrole and its derivatives, but the disclosure is not necessarily limited thereto.

The adhesion promoting material SAM′ may be a self-assembled material, and include at least one material among, for example, (3-aminopropyl)trimethoxysilane (APS), 11-mercaptoundecanoic acid (MUA), (3-trimethoxysilylpropyl)diethylenetriamine (DET), N-(2-aminoethyl)-3-aminopropyltrimethoxysilane (EDA), vinyltriethoxysilane (VTES), 3-glycidoxypropyltrimethoxysilane (GPTMS), 3-methacryloxypropyltrimethoxysilane (MPTMS), perfluorodecyltrichlorosilane (PFS), octadecyltrichlorosilane (OTS), octadecyltrimethoxysilane (OTMS), 1-hexadecanethiol (HDT), (heptadecafluoro-1,1,2,2,-tetrahydrodecyl)trichlorosilane (FDTS), 1H,1H,2H,2H-perfluorodecyltrichlorosilane-perfluorodecyltrichlorosilane (FOTS), pentafluorobenzenethiol (PFBT), and dichlorodimethylsilane (DDMS), but the disclosure is not necessarily limited thereto.

In case that the adhesion promoting material SAM′ includes a self-assembled material, the adhesion promoting material SAM′ may be chemically adsorbed on the surface of the pixel electrode 170, so that a self-assembled monolayer may be formed. A reactive group of the adhesion promoting layer SAM′ may be chemically bonded to the surface (e.g., directly to the surface) of the pixel electrode 170.

In some embodiments, the adhesion promoting material SAM′ may further include a surfactant. The surfactant is not particularly limited, and may include a nonionic surfactant, a cationic surfactant, and/or an anionic surfactant, which are used in the art.

The mixed ink MI may be coated in the opening of the pixel defining layer 126 through, for example, an inkjet printing process. The mixed ink MI may be extracted from an inkjet printing apparatus IP to be coated in each of areas defined by the pixel defining layer 126. As described above, since the wettability may be improved by the fluoro group of the surface of the pixel defining layer 126, the mixed ink MI can be prevented from invading a light emitting area EMA of an adjacent pixel PX beyond the pixel defining layer 126. Thus, the mixed ink MI can be locally coated in the opening of the pixel defining layer 126.

Referring to FIG. 10, subsequently, an adhesion promoting layer SAM and the hole injection layer 191 may be formed for each pixel PX by drying a solvent of the mixed ink MI. As described above, in case that the adhesion promoting layer SAM and the hole injection layer 191 are formed through the same process by using the mixed ink MI, the hole injection layer 191 may contain a very small amount of the adhesion promoting material SAM′.

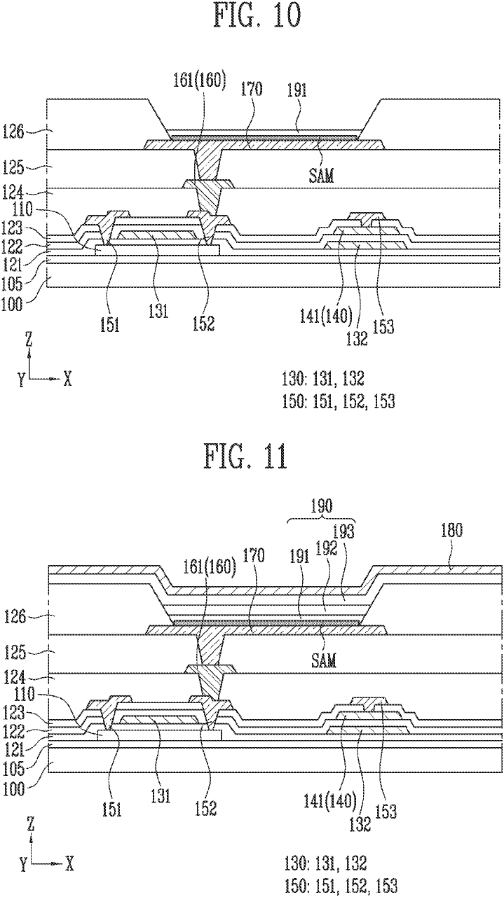

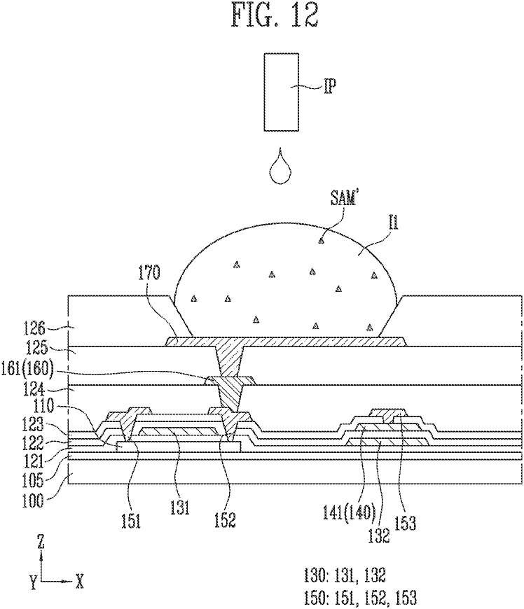

Referring to FIG. 11, a light emitting layer 192, an electron injection layer 193, and a common electrode 180 may be formed on the hole injection layer 191. The light emitting layer 192 may be formed through the above-described inkjet printing process, but the disclosure is not limited thereto. The electron injection layer 193 and/or the common electrode 180 may be formed through a deposition process, and a vacuum deposition process or sputtering may be exemplarily used. However, the disclosure is not limited thereto. The display device shown in FIG. 3 may be completed by forming the light emitting layer 192, the electron injection layer 193, and the common electrode 180.

According to a method in accordance with the above-described embodiment, the repellant may be provided to the surface of the pixel defining layer 126 by introducing the fluoro group onto the surface of the pixel defining layer 126 through the plasma treatment P, so that the light emitting device layer 190 can be easily formed in the opening of the pixel defining layer 126.

The mixed ink MI may include not only the hole injection material 191′ but also the adhesion promoting material SAM′, so that the wettability of the mixed ink MI with respect to the pixel electrode 170 can be improved. Thus, the hole injection layer 191 may be uniformly formed while being adhered closely onto the one surface of the pixel electrode 170, and thus hole injectability and light emitting efficiency can be improved.

Hereinafter, a method of manufacturing the display device in accordance with another embodiment of the disclosure will be described. Redundant descriptions will be omitted, and portions different from those of the above-described embodiment will be described.

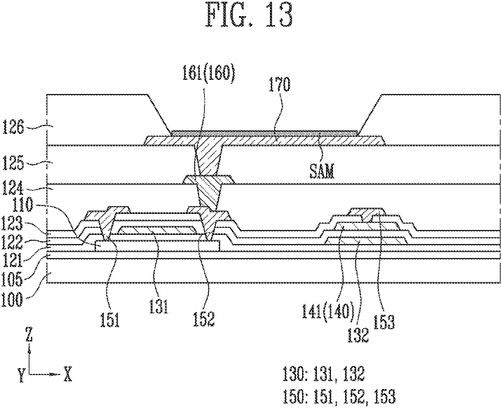

FIGS. 12 to 15 are schematic sectional views illustrating process steps in a method of manufacturing a display device in accordance with another embodiment of the disclosure.

FIGS. 12 to 15 illustrate some processes of the method, and may correspond to the process steps shown in FIGS. 9 and 10. The method in accordance with this embodiment may be different from the process steps shown in FIGS. 9 and 10, in that each of the adhesion promoting layer SAM and the hole injection layer 191 may be formed after the plasma treatment P shown in FIG. 8.

Referring to FIG. 12, a first ink I1 may be provided on a pixel electrode 170 exposed by an opening of a pixel defining layer 126. The first ink I1 may include a self-assembled material as an adhesion promoting material SAM′ dispersed in a solvent. A reactive group of the adhesion promoting layer SAM′ may be chemically bonded to a surface (e.g., directly to a surface) of a pixel electrode 170. The adhesion promoting material SAM′ has been described with reference to FIG. 9, and therefore, redundant descriptions will be omitted. The first ink I1 may be coated in the opening of the pixel defining layer 126 through, for example, an inkjet printing process. The first ink I1 may be extracted from an inkjet printing apparatus IP to be locally coated in an area defined by the pixel defining layer 126. Accordingly, surface characteristics of the pixel electrode 170 can be easily controlled while minimizing the repellant of a top surface of the pixel defining layer 126 from being deteriorated by the first ink I1.

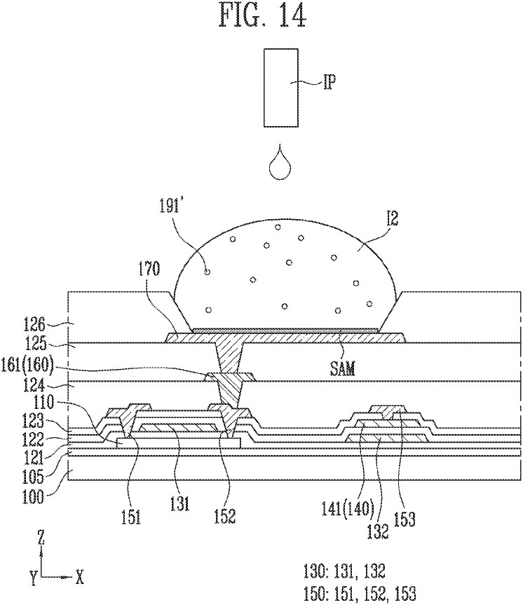

Referring to FIG. 13, subsequently, an adhesion promoting layer SAM may be formed for each pixel PX by drying the solvent of the first ink I1. The adhesion promoting layer SAM may be a self-assembled monolayer, and be chemically adsorbed on the surface of the pixel electrode 170, to easily control the surface characteristics of the pixel electrode 170. Accordingly, the wettability of a second ink I2 with respect to the pixel electrode 170 can be improved, and thus device characteristics can be improved.

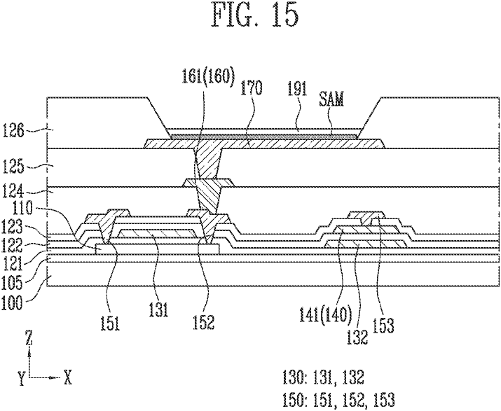

Referring to FIG. 14, subsequently, the second ink I2 may be provided on the adhesion promoting layer SAM in the opening of the pixel defining layer 126. The second ink I2 may include a hole injection material 191′ dispersed in a solvent. The hole injection material 191′ has been described with reference to FIG. 9, and therefore, redundant descriptions will be omitted. The second ink I2 may be coated in the opening of the pixel defining layer 126 through, for example, the above-described inkjet printing process. The second ink I2 may be extracted from an inkjet printing apparatus IP to be coated in each of areas defined by the pixel defining layer 126. The wettability of the second ink I2 can be improved by the adhesion promoting layer SAM, and thus the second ink I2 can be uniformly coated on the pixel electrode 170.

Referring to FIG. 15, subsequently, a hole injection layer 191 may be formed on the adhesion promoting layer SAM by drying the solvent of the second ink I2. Subsequently, the display device shown in FIG. 3 may be manufactured by performing subsequent processes substantially similar to those shown in FIG. 11.

According to the method in accordance with this embodiment, the adhesion promoting layer SAM may be formed on the pixel electrode 170, and the second ink I2 for forming the hole injection layer 191 may be provided on the adhesion promoting layer SAM, so that the wettability of the second ink I2 with respect to the pixel electrode 170 can be improved. Accordingly, the hole injection layer 191 can be uniformly formed while being adhered closely onto the one surface of the pixel electrode 170, and thus hole injectability and light emitting efficiency can be improved.

While the invention has been described in connection with the embodiments, it will be understood by those skilled in the art that various modifications and changes can be made thereto without departing from the spirit and scope of the invention defined by the appended claims.

Thus, the scope of the invention should not be limited by the particular embodiments described herein but should be defined by the appended claims and equivalents thereof.

What is claimed is:

1. A method of manufacturing a display device, the method comprising:
disposing a pixel electrode on a substrate;
disposing, on the substrate, a pixel defining layer including an opening exposing the pixel electrode;
disposing an adhesion promoting layer and a hole injection layer in the opening of the pixel defining layer; and
disposing a light emitting layer on the hole injection layer.

2. The method of claim 1, wherein the disposing of the adhesion promoting layer and the hole injection layer includes disposing, in the opening, an ink which includes an adhesion promoting material and a hole injection material.

3. The method of claim 2, wherein the adhesion promoting material includes a self-assembled material.

4. The method of claim 3, wherein the adhesion promoting material includes a surfactant.

5. The method of claim 1, wherein the disposing of the adhesion promoting layer and the hole injection layer includes:
disposing the adhesion promoting layer by disposing an adhesion promoting material in the opening; and
disposing a hole injection material on the adhesion promoting layer.

6. The method of claim 5, wherein the adhesion promoting material and the hole injection material are disposed through inkjet printing.

7. The method of claim 1, wherein the disposing of the pixel defining layer includes performing plasma treatment on a surface of the pixel defining layer.

8. The method of claim 7, wherein, the performing of the plasma treatment includes disposing liquid repellency on the surface of the pixel defining layer by introducing a fluoro group onto the surface of the pixel defining layer.

9. The method of claim 7, wherein the plasma treatment uses a reactive gas including at least one of SiF4, CF4, C3F8, C2F6, CHF3, CClF3, NF3, and SF6.
